(19) United States
(12) Patent Application Publication
(10) Pub. No.: US 2023/0216035 A1
(43) Pub. Date: Jul. 6, 2023

(54) ULTRA-FAST CHARGING HIGH-CAPACITY PHOSPHORENE COMPOSITE ACTIVATED CARBON MATERIAL FOR BATTERY APPLICATION

(71) Applicant: Electjet Corp., Missouri City, TX (US)

(72) Inventors: Samuel Gong, Brentwood, TN (US); Lin Weijia, Shenzhen (CN)

(21) Appl. No.: 18/092,730

(22) Filed: Jan. 3, 2023

Related U.S. Application Data
(60) Provisional application No. 63/296,485, filed on Jan. 5, 2022.

(51) Int. Cl. H01M 4/36; H01M 4/587; H01M 4/04; H01M 4/133; H01M 4/1393; H01M 4/62; C23C 16/30; C23C 18/12

(52) U.S. Cl. CPC H01M 4/366; H01M 4/587; H01M 4/0428; H01M 4/133; H01M 4/1393; H01M 4/0404; H01M 4/625; H01M 4/622; H01M 4/0471; H01M 4/0435; C23C 16/30; C23C 18/1204; C23C 18/1245; H01M 2004/027

(57) ABSTRACT

An ultra-fast charging, high-capacity composite material for use with anodes in lithium-ion batteries including a phosphorene layer on a carbon-based negative electrode material. The carbon-based negative electrode material may be activated carbon, graphene, carbon nanotubes, or combinations thereof. The phosphorene layer includes a base layer of black phosphorus upon which is deposited activated carbon having a disclosed range of particle size and surface area. In a second embodiment, the negative electrode material is a composite of activated carbon and black carbon and includes a negative electrode current collector of copper foil. A slurry is made from a carbon-based conductive agent and a binder, and applied to both sides of the copper foil, then heated and compacted with a rolling machine. The anodes thus produced are used in making lithium-ion batteries, capacitors, etc.

### RELATIONSHIP TO OTHER APPLICATIONS

This application claims the benefit of U.S. provisional Patent Application Ser. No. 63/296,485 filed Jan. 5, 2022 to the same inventors.

### FIELD OF THE INVENTION

The present invention generally relates to rechargeable batteries and, more particularly, for an ultra-fast charging, high-capacity composite material for use with anodes in lithium-ion batteries.

### BACKGROUND OF THE INVENTION

Rechargeable batteries are commonly used in everything from gaming devices to cellphones. The good thing about such types of batteries is that they make charging and recharging the underlying device very convenient. A shortcoming of rechargeable batteries is that they degrade and become less useful over time. Such degrading results in increasing charging times and fewer charging cycles before the device batteries need to be replaced.

### BRIEF DESCRIPTION OF THE DRAWING

The present invention will hereinafter be described in conjunction with the following drawing figures, wherein like numerals denote like elements, and

FIG. 1 is a process diagram illustrating an exemplary embodiment of the method of making an ultra-fast charging high-capacity phosphorene composite activated carbon material for battery application, according to a preferred embodiment of the present invention; and

FIG. 2 is a process diagram illustrating exemplary details of a second embodiment of the method of making an ultra-fast charging high-capacity phosphorene composite activated carbon material for battery application, according to a preferred embodiment of the present invention.

### DESCRIPTION OF THE INVENTION

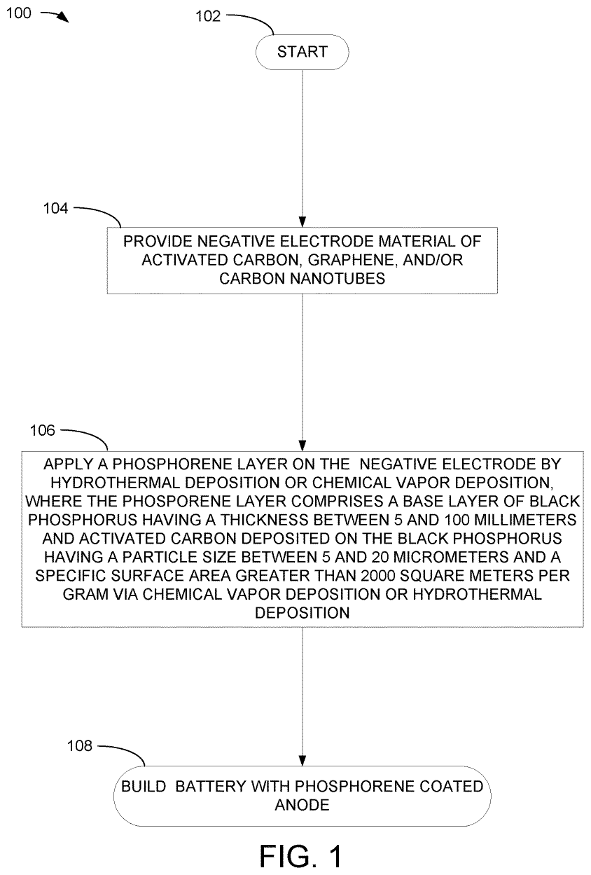

FIG. 1 is a process diagram illustrating an exemplary embodiment of the method of making an ultra-fast charging high-capacity phosphorene composite activated carbon material for battery application, according to a preferred embodiment of the present invention. The present invention is directed to an ultra-fast charging high-capacity phosphorene composite activated carbon material used in conjunction with anodes of rechargeable batteries, such as lithium-ion batteries. In an exemplary embodiment 100, the method starts 102 with providing the necessary equipment for the process. In step 104, a negative electrode (anode) material, formed in the appropriate shape and size for a battery to be constructed, is provided. The negative electrode material may be one of more of activated carbon, graphene, and/or carbon nanotubes. In step 106, the composite anode is formed by coating a phosphorene layer on the surface of the negative electrode material. The phosphorene layer is made by hydrothermal synthesis or CVD (Chemical vapor deposition) with activated carbon. The phosphorene layer is comprised of a base layer of black phosphorus having a thickness from between about 5-100 millimeters. A layer of activated carbon material having a particle size of between about 5-20 micrometers and a specific surface area greater than 2000 square meters per gram is deposited on the black phosphorus material via chemical vapor deposition or other suitable mechanism (e.g. Hydrothermal deposition). In additional embodiments of the present invention, the composite material may be formed from carbon nanotubes orgraphene.

The gram capacity of the activated carbon can ensure intrinsic double layer adsorption of activated carbon, combined with the rapid reaction of phosphorene, so that the composite material has both high capacity and ultra-fast rate. For example, coating a lithium-ion battery with the composite material increases charging rate 5-10% times that of standard graphite materials. Also, the number of battery recharges is significantly increased as compared to standard graphite material. The present invention guarantees the ultra-fast rate charge and discharge performance of the material, improves the capacity per gram of materials, and broadens the application field, for example, from electric double layer capacitors to lithium-ion capacitors and lithium-ion batteries.

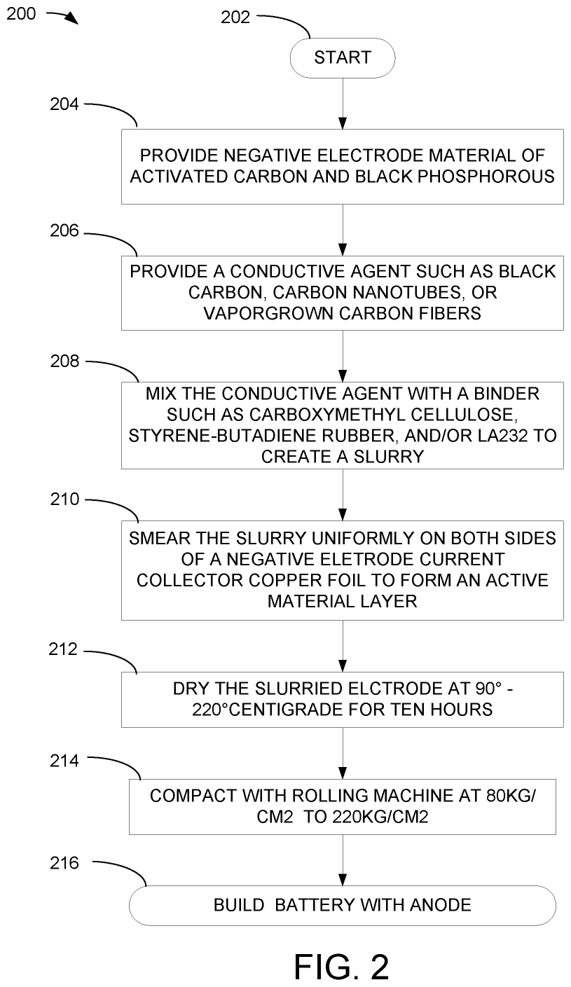

FIG. 2 is a process diagram illustrating exemplary details of a second embodiment of the method of making an ultra-fast charging high-capacity phosphorene composite activated carbon material for battery application 200, according to a preferred embodiment of the present invention. Step 202 begins the preparation of a phosphorene composite activated carbon negative electrode for ultra-fast charging and high-capacity lithium-ion batteries or lithium-ion capacitors by assembling the necessary equipment for the process. The negative electrode active material is mainly composed of activated carbon and black phosphorous material, and the mass of black phosphorous in the composite material is 10% of the total mass of the composite material. Black phosphorus is coated with activated carbon by hydrothermal liquid phase method or chemical vapor deposition method. In step 204, a negative electrode material is provided in the form, size, and shape for the intended application, for example, without limitation, a lithium-ion battery. The negative electrode material includes a negative electrode current collector copper foil. In step 206, a conductive agent including, for examples and without limitation, black carbon, carbon nanotubes (CNT), or vapor-grown carbon fibers (VGCF), is provided. In step 208, the negative electrode active material is mixed with the conductive agent and a binder which comprises, for non-limiting examples, carboxymethyl cellulose (CMC), styrene-butadiene rubber (SBR), and/or an acrylonitrile multi-copolymer binder (LA232), to form a slurry. In step 210, the slurry is uniformly smeared on both sides of the negative electrode current collector copper foil to form an active material layer. In step 212, the slurry-coated electrode is dried at 90 degrees Centigrade to 120 degrees Centigrade for ten hours. In step 214, the dried slurry-coated electrode is compacted, using a rolling machine with rolling pressure of 80 kilograms per square centimeter to 120 kilograms per square centimeter, to obtain a negative electrode sheet. In step 216, a negative pole piece (anode) prepared by the above method and a lithium piece are assembled into a half-cell button battery for capacity test. The test results are as follows: the lithium insertion gram capacity of artificial graphite is 370 milliamp-hour per gram, the lithium removal gram capacity (delithiation) is 340 milliamp-hour per gram, and the first coulombic efficiency is 91.9%. The delithiation capacity of activated carbon is 60 milliamp-hour per gram, and the first coulombic efficiency is 80.0%. The delithiation capacity of the phosphorene composite activated carbon of the present invention is 310 milliamp-hour per gram, and the first coulombic efficiency is 86.1%.

The following claims contain some functional claiming elements and do not contain any statements of intended use.

We claim:

1. A method of making an ultra-fast charging high-capacity phosphorene composite activated carbon material for battery application, comprising the steps of:
a) providing a negative electrode material made of carbon;
b) applying a phosphorene layer on said negative electrode material via one of: chemical vapor deposition and hydrothermal deposition; and
c) constructing a battery with said phosphorene-layered negative electrode material.

2. The method of claim 1, wherein said negative electrode material made of carbon comprises one or more of:
a) activated carbon;
b) graphene; and
c) carbon nanotubes.

3. The method of claim 1, wherein said phosphorene layer comprises:
a) a base layer of black phosphorus having a thickness between five millimeters and one hundred millimeters;
b) activated carbon deposited on said base layer and having a particle size five micrometers and twenty micrometers and having a surface area greater than two thousand square meters per gram; and
c) wherein said deposition comprises at least one of:
i) chemical vapor deposition; and
ii) hydrothermal deposition.

4. A method of making an ultra-fast charging high-capacity phosphorene composite activated carbon material for battery application, comprising the steps of:
a) providing a composite negative electrode material comprising activated carbon and black phosphorus and comprising a negative current collector copper foil;
b) providing a conductive agent;
c) mixing said conductive agent with a binder to from a slurry;
d) smearing said slurry uniformly on both sides of said negative current collector copper foil to form an active material layer;
e) drying said slurry-smeared electrode;
f) compacting said dried slurry-smeared electrode to form an electrode sheet.

5. The method of claim 4, wherein said black phosphorous in said composite negative electrode material comprises ten percent of the total mass of the composite negative electrode material.

6. The method of claim 4, wherein said conductive agent comprises at least one of:
a) carbon nanotubes;
b) black carbon; and
c) vapor-grown carbon fibers.

7. The method of claim 4, wherein said binder is at least one of:
a) carboxymethyl cellulose;
b) styrene-butadiene rubber; and
c) an acrylonitrile multi-copolymer binder (LA232).

8. The method of claim 4, wherein said drying comprises drying at ninety degrees Centigrade to two-hundred-twenty degrees Centigrade for ten hours.

9. The method of claim 4, wherein said compacting comprises the use of a rolling machine a a pressure of between eighty kilograms per square centimeter and two-hundred-twenty kilograms per square centimeter.

10. The method of claim 4, comprising a final step of constructing a battery using said electrode sheet.

11. A method of making an ultra-fast charging high-capacity phosphorene composite activated carbon material for battery application, comprising the steps of:
a) providing a composite negative electrode material comprising activated carbon and black phosphorus and comprising a negative current collector copper foil;
b) providing a conductive agent;
c) mixing said conductive agent with a binder to from a slurry;
d) smearing said slurry uniformly on both sides of said negative current collector copper foil to form an active material layer;
e) drying said slurry-smeared electrode;
f) compacting said dried slurry-smeared electrode to form an electrode sheet; and
g) wherein said black phosphorous in said composite negative electrode material comprises ten percent of the total mass of the composite negative electrode material.

12. The method of claim 11 wherein:
a) said conductive agent comprises at least one of:
i) carbon nanotubes;
ii) black carbon; and
iii) vapor-grown carbon fibers; and
b) said binder is at least one of:
i) carboxymethyl cellulose;
ii) styrene-butadiene rubber; and
iii) an acrylonitrile multi-copolymer binder (LA232).

13. The method of claim 11, wherein said drying comprises drying at ninety degrees Centigrade to two-hundred-twenty degrees Centigrade for ten hours.

14. The method of claim 11, wherein said compacting comprises the use of a rolling machine a a pressure of between eighty kilograms per square centimeter and two-hundred-twenty kilograms per square centimeter.

15. The method of claim 11, comprising a final step of constructing a battery using said electrode sheet.

16. A method of making an ultra-fast charging high-capacity phosphorene composite activated carbon material for battery application, comprising one of:
a) the steps of:
i) providing a negative electrode material made of carbon;
ii) applying a phosphorene layer on said negative electrode material via one of: chemical vapor deposition and hydrothermal deposition; and
iii) constructing a battery with said phosphorene-layered negative electrode material.
iv) wherein said negative electrode material made of carbon comprises one or more of:
(1) activated carbon;
(2) graphene; and
(3) carbon nanotubes;
v) wherein said phosphorene layer comprises:
vi) a base layer of black phosphorus having a thickness between five millimeters and one hundred millimeters;
vii) activated carbon deposited on said base layer and having a particle size five micrometers and twenty micrometers and having a surface area greater than two thousand square meters per gram; and
viii) wherein said deposition comprises at least one of:
(1) chemical vapor deposition; and
(2) hydrothermal deposition; and
b) the steps of:
i) A method of making an ultra-fast charging high-capacity phosphorene composite activated carbon material for battery application, comprising the steps of:
(1) providing a composite negative electrode material comprising activated carbon and black phosphorus and comprising a negative current collector copper foil;
(2) providing a conductive agent;
(3) mixing said conductive agent with a binder to from a slurry;
(4) smearing said slurry uniformly on both sides of said negative current collector copper foil to form an active material layer;
(5) drying said slurry-smeared electrode;
(6) compacting said dried slurry-smeared electrode to form an electrode sheet; and
(7) wherein said black phosphorous in said composite negative electrode material comprises ten percent of the total mass of the composite negative electrode material.

17. The method of claim 16 wherein:
a) said conductive agent comprises at least one of:
i) carbon nanotubes;
ii) black carbon; and
iii) vapor-grown carbon fibers; and
b) said binder is at least one of:
i) carboxymethyl cellulose;
ii) styrene-butadiene rubber; and
iii) an acrylonitrile multi-copolymer binder (LA232).

18. The method of claim 16, wherein said drying comprises drying at ninety degrees Centigrade to two-hundred-twenty degrees Centigrade for ten hours.

19. The method of claim 16, wherein said compacting comprises the use of a rolling machine at a pressure of between eighty kilograms per square centimeter and two-hundred-twenty kilograms per square centimeter.

20. The method of claim 16, comprising a final step of constructing a battery using said electrode sheet.
